(19) United States
(12) Patent Application Publication
(10) Pub. No.: US 2014/0239289 A1
(43) Pub. Date: Aug. 28, 2014

(54) SEMICONDUCTOR DEVICE AND METHOD FOR MANUFACTURING THE SAME

(71) Applicant: KABUSHIKI KAISHA TOSHIBA, Tokyo (JP)

(72) Inventors: Tetsu MOROOKA, Kanagawa-ken (JP); Tatsuya OHGURO, Kanagawa-ken (JP); Hisayo MOMOSE, Kanagawa-ken (JP); Kazuya FUKASE, Tokyo (JP)

(73) Assignees: EPAS; KABUSHIKI KAISHA TOSHIBA, Tokyo (JP)

(21) Appl. No.: 13/926,971

(22) Filed: Jun. 25, 2013

(30) Foreign Application Priority Data
Feb. 26, 2013 (JP) 2013-036470

(51) Int. Cl. H01L 29/786

(52) U.S. Cl. CPC H01L 29/7869
USPC 257/43; 438/104

(57) ABSTRACT

In general, according to one embodiment, a semiconductor device includes a first electrode, an oxide semiconductor film, an insulating film, a first protective film, second and third electrodes. The oxide semiconductor film is provided on the first electrode. The oxide semiconductor film includes a first face on the first electrodes side and a second face on a side opposite to the first face. The insulating film is provided between the first electrode and the oxide semiconductor film. The first protective film includes a first film provided between the insulating film and the first face and a second film provided on the second face. The first protective film suppresses substances including hydrogen from being introduced from an outer side of the oxide semiconductor film to an inner side of the oxide semiconductor film. The second electrode and the third electrode are electrically connected to the oxide semiconductor film.

### CROSS-REFERENCE TO RELATED APPLICATIONS

This application is based upon and claims the benefit of priority from Japanese Patent Application No.2013-036470, filed on Feb. 26, 2013; the entire contents of which are incorporated herein by reference.

### FIELD

Embodiments described herein relate generally to a semiconductor device and method for manufacturing the same.

### BACKGROUND

Semiconductor devices, such as a thin film transistor (TFT), are widely used in image display devices including liquid crystal display devices, organic electro luminescence (EL) display devices, and the like. In recent years, semiconductor devices are being developed that use an oxide semiconductor in which In—Ga—Zn—O or the like is used as an active layer semiconductor film. Oxide semiconductors are known for easy fabrication even at low temperatures and for having high mobility of at least 10 cm²/Vs. In a semiconductor device using an oxide semiconductor, the stabilization of characteristics is critical.

### BRIEF DESCRIPTION OF THE DRAWINGS

FIG. 1A and 1B are schematic views illustrating a semiconductor device according to a first embodiment;

FIG. 2A to FIG. 2D are schematic cross-sectional views showing a method for manufacturing the semiconductor device;

FIG. 3A and FIG. 3B are schematic views illustrating examples of a semiconductor device according to a second embodiment;

FIG. 4A to FIG. 6D are schematic cross-sectional views showing one example of the method for manufacturing the semiconductor device;

FIG. 7A and 7B are schematic views illustrating a semiconductor device according to a third embodiment.

FIGS. 8A to 11C are schematic cross-sectional views showing one example of the method for manufacturing the semiconductor device; and

FIG. 12 is a schematic cross-sectional view illustrating an example of a semiconductor device according to the fourth embodiment.

### DETAILED DESCRIPTION

In general, according to one embodiment, a semiconductor device includes a first electrode, an oxide semiconductor film, an insulating film, a first protective film, a second electrode, and a third electrode. The oxide semiconductor film is provided on the first electrode. The oxide semiconductor film includes a first face on the first electrodes side and a second face on a side opposite to the first face. The insulating film is provided between the first electrode and the oxide semiconductor film. The first protective film includes a first film provided between the insulating film and the first face and a second film provided on the second face. The first protective film suppresses substances including hydrogen from being introduced from an outer side of the oxide semiconductor film into an inner side of the oxide semiconductor film. The second electrode is electrically connected to the oxide semiconductor film. The third electrode is electrically connected to the oxide semiconductor film.

Various embodiments will be described hereinafter with reference to the accompanying drawings.

In the following description, the same reference numeral is applied to the same member, and for members that have been described once, the description is omitted as appropriate.

### First Embodiment

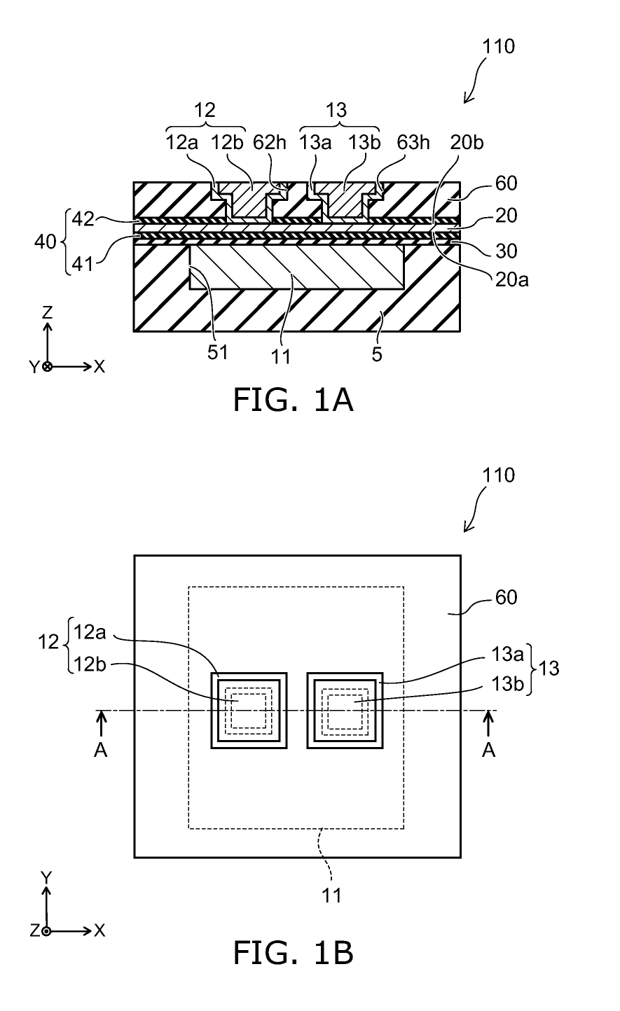

FIGS. 1A and 1B are schematic views illustrating a semiconductor device according to a first embodiment.

FIG. 1A shows a schematic cross-sectional view of a semiconductor device 110 according to the first embodiment. FIG. 1B shows a schematic plan view of the semiconductor device 110 according to the first embodiment. The schematic cross-sectional view shown in FIG. 1A is a cross-sectional view along A-A of FIG. 1B.

The semiconductor device 110, as shown in FIG. 1A, includes a first electrode 11, an oxide semiconductor film 20, an insulating film 30, a first protective film 40, a second electrode 12, and a third electrode 13. The semiconductor device 110 is, for example, a TFT. The first electrode 11 is, for example, a gate electrode for the TFT. The second electrode 12 is, for example, a source electrode for the TFT. The third electrode 13 is, for example, a drain electrode for the TFT. The oxide semiconductor film 20 is, for example, an active layer where a channel for the TFT is formed. The insulating film 30 is, for example, a portion of the gate insulating film for the TFT.

In the semiconductor device 110, the oxide semiconductor film 20 is provided between the first electrode 11 and the second electrode 12 and between the first electrode 11 and the third electrode 13. Note that the first electrode 11, the second electrode 12, and the third electrode 13 may be provided together with on the oxide semiconductor film 20.

The first electrode 11 is embedded in a groove 51 provided in an insulating portion 5. Copper (Cu) may be used, for example, for the first electrode 11. The first electrode 11 is formed by, for example, a damascene method. In this embodiment, the first electrode 11 is embedded in the groove 51 of the insulating portion 5 by the damascene method using Cu. The first electrode 11, as shown in FIG. 1B, is provided in, for example, an island shape. The first electrode 11 may also be provided in a line shape.

The oxide semiconductor film 20 is provided on the first electrode 11. In this embodiment, a direction connecting the first electrode 11 and the oxide semiconductor film 20 is referred to as a Z direction, one of directions orthogonal to the Z direction is referred to as an X direction, and a direction orthogonal to both the Z direction and the X direction is referred to as a Y direction.

The oxide semiconductor film 20 includes a first face 20a on the first electrode 11 side and a second face 20b on a side opposite to the first face 20a. The first face 20a is, for example, a lower face of the oxide semiconductor film 20. The second face 20b is, for example, an upper face of the oxide semiconductor film 20.

For example, indium (In)—gallium (Ga)—zinc (Zn)—oxygen (O) are provided in the oxide semiconductor film 20. An oxide including In or Zn other than In—Ga—Zn—O, such as In—O film, Zn—O film, In—Zn—O film, In—Ga—O film, Al—Zn—O film, In—Al—Zn—O film or the like may also be used for the oxide semiconductor film 20. A thickness of the oxide semiconductor film 20 may be, for example, not less than 5 nanometers (nm) and not more than 100 nm.

The insulating film 30 is provided between the first electrode 11 and the oxide semiconductor film 20. The insulating film 30 may be stacked, for example, on the first electrode 11. Silicon nitride (SiN), for example, may be used as the insulating film 30. Other than SiN, silicon oxide (SiO₂), silicon oxynitride (SiON), or even HfO₂ or HfON or the like may be used as the insulating film 30. The use of Cu as the first electrode 11 and SiN as the insulating film 30 effectively suppresses the diffusion of Cu into the oxide semiconductor film 20. A thickness of the insulating film 30 may be, for example, not less than 5 nm and not more than 500 nm.

The first protective film 40 includes a first film 41 and a second film 42. The first film 41 is provided between the insulating film 30 and the first face 20a. The first film 41 contacts, for example, the first face 20a. The second film 42 is provided on the second face 20b. The second film 42 contacts, for example, the second face 20b. More specifically, the oxide semiconductor film 20 is provided between the first film 41 and the second film 42.

The first protective film 40 suppresses a foreign material from being introduced from an outer side of the oxide semiconductor film 20 into an inner side thereof. The foreign material includes substances including, for example, hydrogen. The first protective film 40 includes one selected from the group consisting of, for example, aluminum oxide (Al₂O₃), titanium oxide (TiO₂), or tantalum oxide (Ta₂O₅). The material for the first film 41 may be the same as that of the second film 42 or different from that of the second film 42.

The first film 41 is a portion of the gate insulating film. In the semiconductor device 110, the first film 41 and the insulating film 30 are used as gate insulating films. A thickness of the first film 41 may be, for example, not less than 10 nm and not more than 100 nm. The first film 41 functions as a barrier film that suppresses substances (for example, substances including hydrogen) from being introduced into the oxide semiconductor film 20 from below the first film 41.

A thickness of the second film 42 may be, for example, not less than 10 nm and not more than 100 nm. The second film 42 functions as a barrier film that suppresses substances (for example, substances including hydrogen) from being introduced into the oxide semiconductor film 20 from an outer side of the second film 42.

The second electrode 12 is electrically connected to the oxide semiconductor film 20. An interlayer insulating film 60 is provided on the second film 42. The second electrode 12 is provided in a contact hole 62h which is provided in the interlayer insulating film 60 and the second film 42. The contact hole 62h is provided from a surface of the interlayer insulating film 60 to the oxide semiconductor film 20. The second electrode 12 includes, for example, a first barrier film (a second protective film) 12a and a first conductive portion 12b. The first barrier film 12a is formed along an inner wall of the contact hole 62h and on a bottom of the contact hole 62h. The first barrier film 12a contacts the oxide semiconductor film 20 on the bottom of the contact hole 62h. The first conductive portion 12b is embedded in the contact hole 62h with the first barrier film 12a therebetween.

Tantalum nitride (TaN), for example, may be used for the first barrier film 12a. Cu, for example, may be used for the first conductive portion 12b. The first conductive portion 12b is formed in the contact hole 62h using, for example, the damascene method. The first barrier film 12a functions as a barrier film that suppresses the material of the first conductive portion 12b (for example, Cu), or substances included in the first conductive portion 12b (for example, substances including hydrogen), from being introduced into the oxide semiconductor film 20.

The third electrode 13 is electrically connected to the oxide semiconductor film 20. The third electrode 13 is provided in a contact hole 63h which is provided in the interlayer insulating film 60 and the second film 42. The contact hole 63h is provided from the upper face of the interlayer insulating film 60 to the oxide semiconductor film 20. The third electrode 13 includes, for example, a second barrier film (a second protective film) 13a and a second conductive portion 13b. The second barrier film 13a is formed along the inner wall of the contact hole 63h and on the bottom of the contact hole 63h. The second barrier film 13a contacts the oxide semiconductor film 20 on the bottom of the contact hole 63h. The second conductive portion 13b is embedded in the contact hole 63h with the second barrier film 13a therebetween.

TaN, for example, may be used for the second barrier film 13a. Cu, for example, may be used for the second conductive portion 13b. The second conductive portion 13b is formed in the contact hole 63h using, for example, the damascene method. The second barrier film 13a functions as a barrier film that suppresses the material of the second conductive portion 13b (for example, Cu), or substances included in the second conductive portion 13b (for example, substances including hydrogen), from being introduced into the oxide semiconductor film 20.

If the oxide semiconductor film 20 is used here as an active layer, there is a possibility that substances including hydrogen or the like that are introduced from the outer side of the oxide semiconductor film 20 into the inner side thereof may cause a drop in mobility and a drop in threshold voltage, thereby deteriorating the subthreshold characteristics.

For example, when Cu is used as the first electrode 11, using SiN for the insulating film 30 is effective from the perspective of preventing Cu diffusion. In general, SiN is formed using low temperature plasma chemical vapor deposition (CVD). Therefore, the SiN insulating film 30 is likely to include a large amount of hydrogen. When hydrogen included in the SiN insulating film 30 diffuses into the oxide semiconductor film 20, there is a possibility that deterioration in the characteristics may occur as described above.

In the semiconductor device 110, the oxide semiconductor film 20 is sandwiched between the first film 41 and the second film 42 so as to suppress substances including hydrogen or the like from being introduced from the outer side of the oxide semiconductor film 20 into the inner side thereof. By this, a drop in mobility, a drop in threshold voltage, and deterioration of the subthreshold characteristics can be suppressed.

Next, an example of a method for manufacturing the semiconductor device 110 will be described.

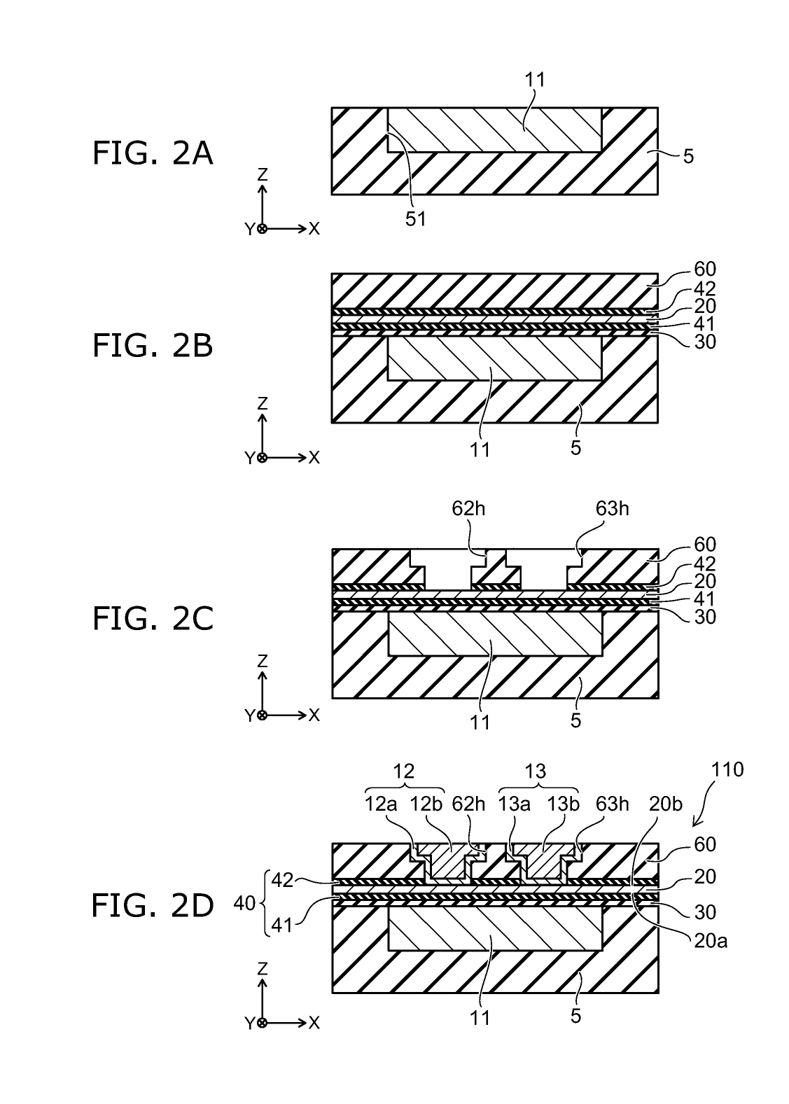

FIG. 2A to FIG. 2D are schematic cross-sectional views showing one example of the method for manufacturing the semiconductor device.

First, as shown in FIG. 2A, the first electrode 11 is formed in the insulating portion 5. The insulating portion 5 is provided, for example, on a substrate not illustrated. The first electrode 11 is formed by, for example, the damascene method. In other words, etching is performed on a portion of the insulating portion 5 to form the groove 51. Next, Cu, for example, is formed on the insulating portion 5 so as to fill in the groove 51. Thereafter, the Cu is removed by chemical mechanical polishing (CMP) to leave only the Cu embedded in the groove 51.

Next, as shown in FIG. 2B, the insulating film 30, the first film 41, the oxide semiconductor film 20, the second film 42, and the interlayer insulating film 60 are stacked in this order on the first electrode 11 and the insulating portion 5. SiN, for example, may be used for the insulating film 30. The insulating film 30 made of SiN can be formed by using, for example, low temperature CVD. A thickness of the insulating film 30 may be, for example, not less than 5 nm and not more than 500 nm, and is preferably not less than 30 nm and not more than 100 nm.

The first film 41 includes one selected from the group consisting of, for example, Al₂O₃, TiO₂, or Ta₂O₅. The first film 41 is formed using, for example, a sputtering method. A thickness of the first film 41 may be, for example, not less than 5 nm and not more than 100 nm.

For example, In—Ga—Zn—O is used for the oxide semiconductor film 20. The oxide semiconductor film 20 is formed using, for example, a sputtering method. A thickness of the oxide semiconductor film 20 may be, for example, not less than 5 nm and not more than 500 nm, and is preferably not less than 30 nm and not more than 100 nm.

The second film 42 includes one selected from the group consisting of, for example, Al₂O₃, TiO₂, or Ta₂O₅. The second film 42 is formed using, for example, a sputtering method. The thickness of the second film 42 may be, for example, not less than 5 nm and not more than 100 nm.

For the interlayer insulating film 60, SiO₂ may, for example, be used. The interlayer insulating film 60 is formed using, for example, CVD. A thickness of the interlayer insulating film 60 may be, for example, not less than 100 nm and not more than 1000 nm.

Next, as shown in FIG. 2C, the contact holes 62h and 63h are formed. The contact holes 62h and 63h are formed in the interlayer insulating film 60 and in the second film 42. The contact holes 62h and 63h are formed by, for example, photolithography and etching. The contact holes 62h and 63h are formed from the upper face of the interlayer insulating film 62 to the oxide semiconductor film 20.

Next, as shown in FIG. 2D, the second electrode 12 and the third electrode 13 are formed. First, the first barrier film 12a is formed on the inner wall and on the bottom of the contact hole 62h, and the second barrier film 13a is formed on the inner wall and on the bottom of the contact hole 63h. The first barrier film 12a and the second barrier film 13a contact the oxide semiconductor film 20, respectively. TaN, for example, is used for the first barrier film 12a and for the second barrier film 13a.

Next, the first conductive portion 12b is formed on the first barrier film 12a in the contact hole 62h, and the second conductive portion 13b is formed on the second barrier film 13a in the contact hole 63h. Cu, for example, is used for the first conductive portion 12b and in the second conductive portion 13b. The first conductive portion 12b and the second conductive portion 13b are formed using, for example, the damascene method. In other words, Cu, for example, is formed on the interlayer insulating film 60 so as to fill in the contact holes 62h and 63h. Thereafter, the Cu is removed using CMP to leave only the Cu embedded in the contact holes 62h and 63h.

Thereafter, a sintering process is performed using hydrogen if, for example, an Si-LSI is on the lower layer of the TFT. The semiconductor device 110 is completed according to the processes given above.

According to the method for manufacturing this type of semiconductor device 110, substances (substances including hydrogen or the like) included in the film in the layer below the first film 41 in the manufacturing process can be suppressed by the first film 41 from being introduced into the oxide semiconductor film 20. Furthermore, when a sintering process or the like is performed after the second electrode 12 and the third electrode 13 are formed, substances (substances including hydrogen or the like) can be suppressed by the second film 42 from being introduced from the second face 20b side into an inner side of the oxide semiconductor film 20. By this, the semiconductor device 110 is provided that suppresses a drop in mobility, a drop in threshold voltage, and deterioration of the subthreshold characteristics.

### Second Embodiment

Next, a second embodiment will be described.

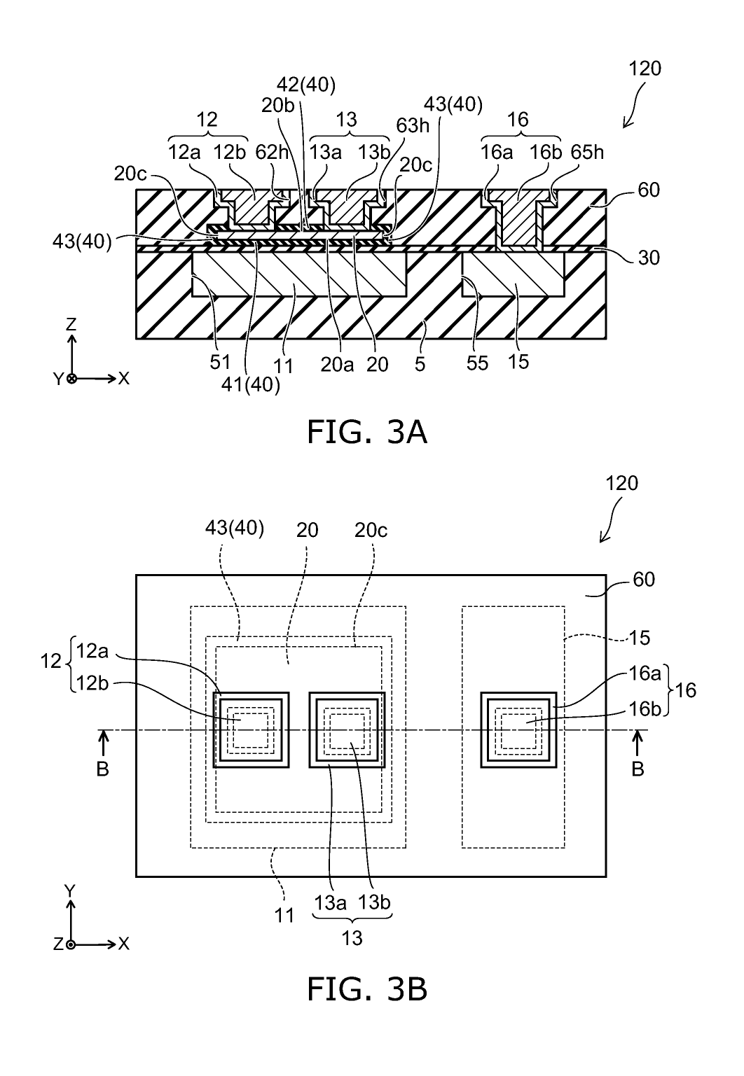

FIGS. 3A and 3B are schematic views illustrating a semiconductor device according to the second embodiment.

FIG. 3A shows a schematic cross-sectional view of the semiconductor device 120 according to the second embodiment. FIG. 3B shows a schematic plan view of the semiconductor device 120 according to the second embodiment. The schematic cross-sectional view shown in FIG. 3A is a cross-sectional view along B-B of FIG. 3B.

The semiconductor device 120, as shown in FIG. 3A, includes a first electrode 11, an oxide semiconductor film 20, an insulating film 30, a first protective film 40, a second electrode 12, and a third electrode 13. The first protective film 40 of the semiconductor device 120 is provided so as to cover the periphery of the oxide semiconductor film 20.

As shown in FIG. 3B, the semiconductor device 120 is provided with the oxide semiconductor film 20 in an island shape. When the oxide semiconductor film 20 has a third face 20c provided between the first face 20a and the second face 20b, the first protective film 40 further has a third film 43 provided on the third face 20c. The third face 20c is, for example, a side face of the oxide semiconductor film 20. The third film 43 is provided so as to cover the side face of the oxide semiconductor film 20. When the third face 20c is provided so as to enclose the periphery of the oxide semiconductor film 20, the third film 43 is also provided so as to enclose the periphery of the oxide semiconductor film 20.

The third film 43 is provided between the first film 41 and the second film 42. In other words, the first film 41 covers the lower face (the first face 20a) of the oxide semiconductor film 20, the second film 42 covers the upper face (the second face 20b) of the oxide semiconductor film 20, and the third film 43 covers the side face (the third face 20c) of the oxide semiconductor film 20.

Note that the side face (the third face 20c) of the oxide semiconductor film 20 may not be definitively provided. In this case, the first protective film 40 covers the periphery of the oxide semiconductor film 20 by joining a edge portion of the first film 41 with an edge portion of the second film 42.

In the semiconductor device 120, because the periphery of the oxide semiconductor film 20 is covered by the first protective film 40, substances including hydrogen or the like are suppressed from being introduced from the perimeter into an inner side of the oxide semiconductor film 20. By this, a drop in mobility, a drop in threshold voltage, and deterioration of the subthreshold characteristics can be suppressed.

Next, an example of a method for manufacturing the semiconductor device 120 will be described.

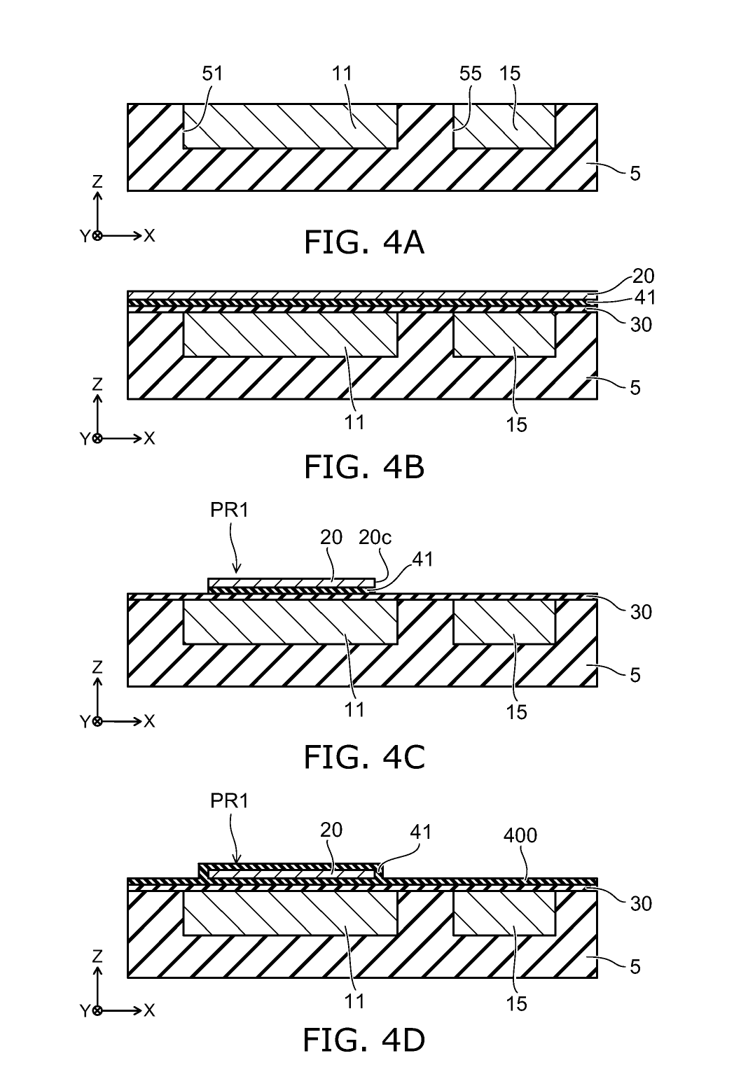

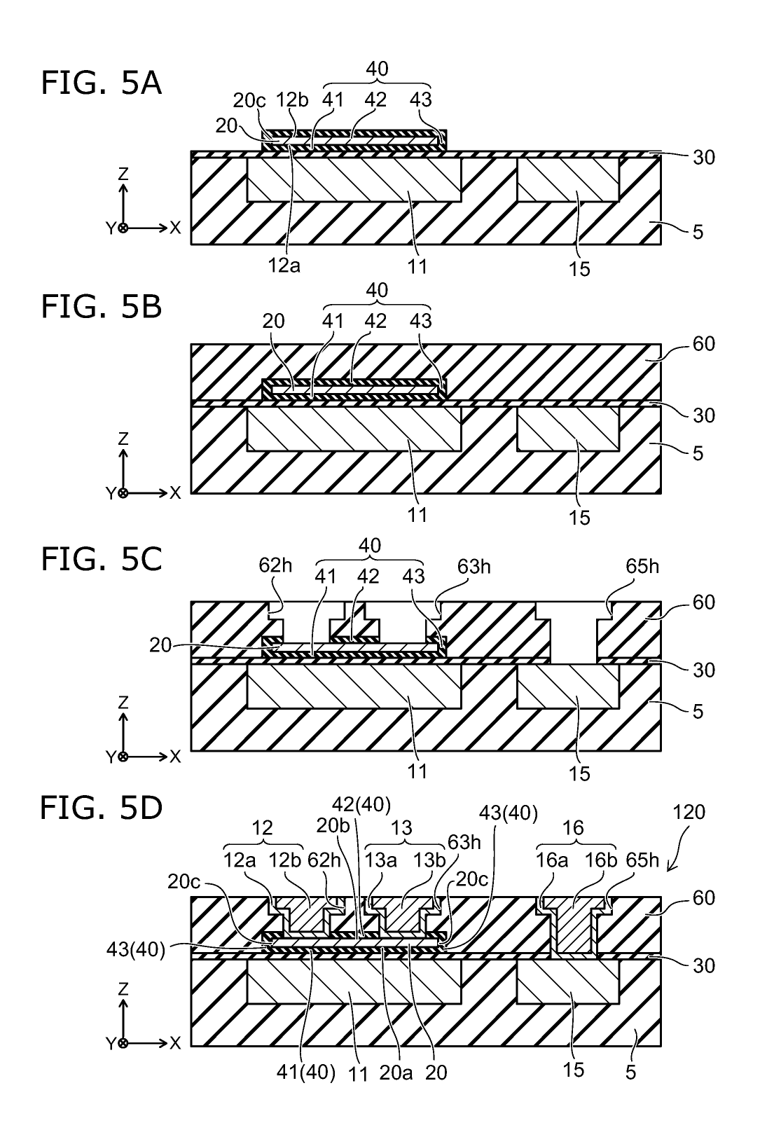

FIG. 4A to FIG. 5D are schematic cross-sectional views showing one example of the method for manufacturing the semiconductor device.

First, as shown in FIG. 4A, the first electrode 11 and an interconnection 15 that conducts with the first electrode 11 are formed in the insulating portion 5. The insulating portion 5 is provided, for example, on a substrate not illustrated. The first electrode 11 and the interconnection 15 are formed by, for example, the damascene method. In other words, etching is performed on a portion of the insulating portion 5 to form the grooves 51 and 55. Next, Cu, for example, is formed on the insulating portion 5 so as to fill in the grooves 51 and 55. Thereafter, the Cu is removed using CMP to leave only the Cu embedded in the grooves 51 and 55.

Next, as shown in FIG. 4B, the insulating film 30, the first film 41, and the oxide semiconductor film 20, are stacked in this order on the first electrode 11, the interconnection 15, and the insulating portion 5. The respective materials, manufacturing methods, and thicknesses of the insulating film 30, the first film 41, and the oxide semiconductor film 20 are similar to the method for manufacturing the semiconductor device 110.

Next, as shown in FIG. 4C, a portion of the oxide semiconductor film 20 and a portion of the first film 41 are removed. The portion of the oxide semiconductor film 20 and the portion of the first film 41 may be removed by, for example, photolithography and etching. The oxide semiconductor film 20 and the first film 41 on the interconnection 15 are removed by the etching. The oxide semiconductor film 20 and the first film 41 on the first electrode 11 are left. By this, a pattern region PR1 of the oxide semiconductor film 20 and the first film 41 is formed on the first electrode 11. The pattern region PR1 is formed in an island shape on the first electrode 11. The side face (the third face 20c) is formed on the oxide semiconductor film 20 by the etching.

Next, as shown in FIG. 4D, a protective film material film 400 is formed so as to cover the pattern region PR1. The protective film material film 400 is formed on the pattern region PR1 and on the insulating film 30. A similar material to that used for, for example, the first film 41 may also be used for the protective film material film 400.

Next, as shown in FIG. 5A, a portion of the protective film material film 400 is removed such that only a portion that covers the pattern region PR1 remains. For example, photolithography and etching may be used so as to leave only the protective film material film 400 on the second face 20b and the protective film material film 400 on the third face 20c of the oxide semiconductor film 20. The protective film material film 400 left on the second face 20b of the oxide semiconductor film 20 by the etching becomes the second film 42. Further, the protective film material film 400 left on the third face 20c of the oxide semiconductor film 20 becomes the third film 43. In other words, the first protective film 40 is formed to enclose the periphery of the oxide semiconductor film 20.

Note that the removal of the portion of the protective film material film 400 shown in FIG. 5A may not always be required. Once a portion of the protective film material film 400 is removed as shown in FIG. 5A, subsequent etching of the protective film material film 400 is no longer necessary when forming the contact hole 65h on the interconnection 15. Therefore, etching conditions are alleviated when forming the contact hole 65h.

Next, as shown in FIG. 5B, the interlayer insulating film 60 is formed on the insulating film 30 and on the first protective film 40. The material, manufacturing method, and the thickness of the interlayer insulating film 60 are similar to the method for manufacturing the semiconductor device 110.

Next, as shown in FIG. 5C, the contact holes 62h, 63h, and 65h are formed. The contact holes 62h and 63h are formed in the interlayer insulating film 60 and in the second film 42. The contact hole 65h is formed in the interlayer insulating film 60 and in the insulating film 30. The contact holes 62h, 63h, and 65h are formed by, for example, photolithography and etching. The contact holes 62h and 63h are formed from the upper face of the interlayer insulating film 62 to the oxide semiconductor film 20. The contact hole 65h is formed from the upper face of the interlayer insulating film 60 to the interconnection 15.

Next, as shown in FIG. 5D, the second electrode 12, the third electrode 13, and an interconnect 16 are formed. First, the first barrier film 12a is formed on the inner wall and bottom of the contact hole 62h, the second barrier film 13a is formed on the inner wall and bottom of the contact hole 63h, and a third barrier film 16a is formed on the inner wall and bottom of the contact hole 65h. The first barrier film 12a and the second barrier film 13a contact the oxide semiconductor film 20, respectively. The third barrier film 16a contacts the interconnection 15. TaN, for example, is used for the first barrier film 12a, in the second barrier film 13a, and in the third barrier film 16a.

Next, the first conductive portion 12b is formed on the first barrier film 12a in the contact hole 62h, the second conductive portion 13b is formed on the second barrier film 13a in the contact hole 63h, and the third conductive portion 16b is formed on the third barrier film 16a in the contact hole 65h. Cu, For example, is used for the first conductive portion 12b, in the second conductive portion 13b, and in the third conductive portion 16b. The first conductive portion 12b, the second conductive portion 13b, and the third conductive portion 16b are formed using, for example, a damascene method. In other words, Cu, for example, is formed on the interlayer insulating film 60 so as to fill in the contact holes 62h, 63h, and 65h. Thereafter, the Cu is removed using CMP to leave only the Cu embedded in the contact holes 62h, 63h, and 65h.

Thereafter, a sintering process is performed using hydrogen if, for example, an Si-LSI is on the lower layer of the TFT. The semiconductor device 120 is completed according to the process given above.

According to the method for manufacturing this type of semiconductor device 120, substances (substances including hydrogen or the like) included in the film in the layer below the first film 41 in the manufacturing process can be suppressed by the first film 41 from being introduced into the oxide semiconductor film 20. Furthermore, when a sintering process or the like is performed after the second electrode 12 and the third electrode 13 are formed, substances (substances including hydrogen or the like) can be suppressed by the second film 42 from being introduced from the second face 20b side and the third face 20c side into an inner side of the oxide semiconductor film 20. By this, the semiconductor device 120 is provided that suppresses a drop in mobility, a drop in threshold voltage, and deterioration of the subthreshold characteristics.

Next, another example of a method for manufacturing the semiconductor device 120 will be described.

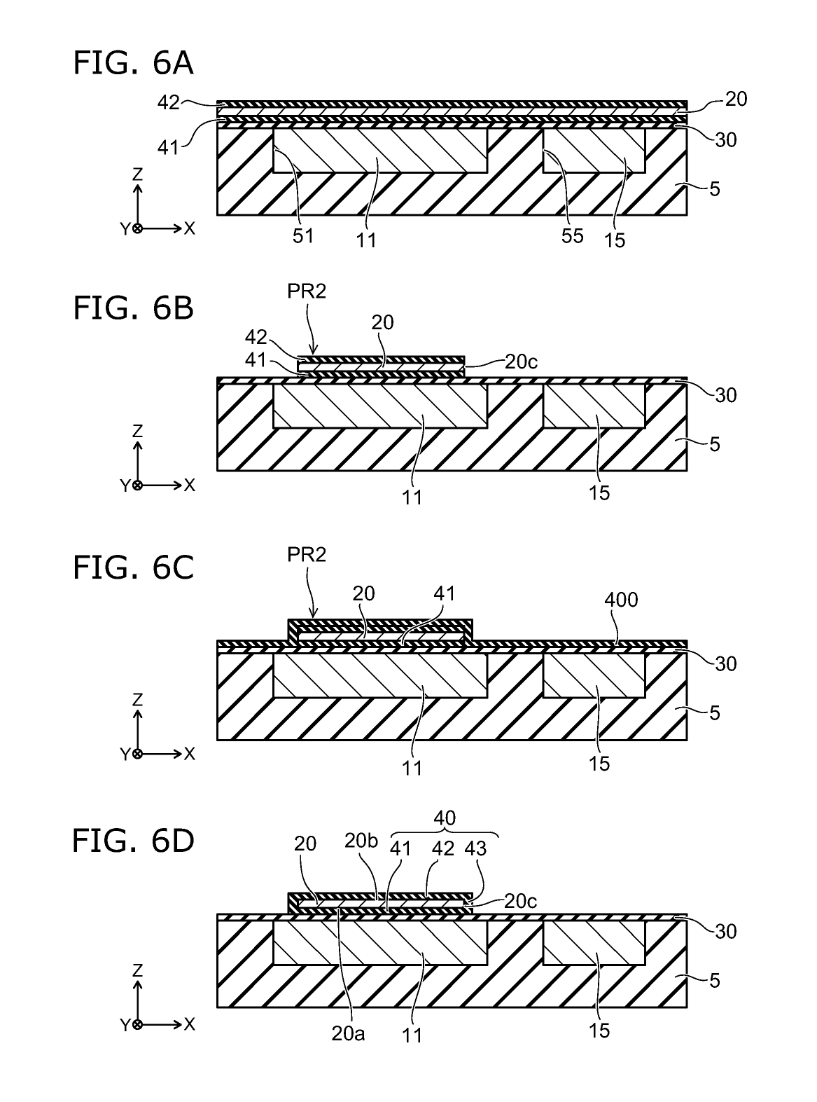

FIGS. 6A to 6D are schematic cross-sectional views showing another example of the method for manufacturing the semiconductor device.

A portion of a process in the method for manufacturing the semiconductor device 120 is shown in FIGS. 6A to 6D.

First, similar to the process shown in FIG. 4A, the first electrode 11 and the interconnection 15 that conducts with the first electrode are formed on the insulating portion 5. Next, as shown in FIG. 6A, the insulating film 30, the first film 41, the oxide semiconductor film 20, and the second film 42 are stacked in this order on the first electrode 11, the interconnection 15, and the insulating portion 5. The respective materials, manufacturing methods, and thicknesses of the insulating film 30, the first film 41, the oxide semiconductor film 20, and the second film 42 are similar to the method for manufacturing the semiconductor device 110.

Next, as shown in FIG. 6B, a portion of the second film 42, a portion of the oxide semiconductor film 20, and a portion of the first film 41 are removed. The portion of the second film 42, the portion of the oxide semiconductor film 20, and the portion of the first film 41 may be removed by, for example, photolithography and etching. The second film 42, the oxide semiconductor film 20, and the first film 41 on the interconnection 15 are removed by the etching. The second film 42, the oxide semiconductor film 20, and the first film 41 on the first electrode 11 are left. By this, a pattern region PR2 of the second film 42, the oxide semiconductor film 20, and the first film 41 is formed on the first electrode 11. The pattern region PR2 is formed in an island shape on the first electrode 11. The side face (the third face 20c) is formed on the oxide semiconductor film 20 by the etching.

Next, as shown in FIG. 6C, a protective film material film 400 is formed so as to cover the pattern region PR2. The protective film material film 400 is formed on the pattern region PR2 (including on the third face 20c) and on the insulating film 30. A similar material to that used for, for example, the first film 41 may also be used for the protective film material film 400.

Next, as shown in FIG. 6D, the protective film material film 400 is etched back. The protective film material film 400 is etched back only an amount equal to the thickness of the protective film material film 400 formed on the insulating film 30. An anisotropic etching is used for the etching back. The etching rate in the Z direction of the anisotropic etching is greater than the etching rates in the X direction and the Y direction. The protective film material film 400 on the insulating film 30 and the protective film material film 400 on the second film 42 are removed by the etching back. The protective film material film 400 provided on the third face 20c is left. The protective film material film 400 left on the third face 20c becomes the third film 43. In other words, the first protective film 40 is formed to enclose the periphery of the oxide semiconductor film 20.

The subsequent processes are the same as those shown in FIGS. 5B to 5D. The semiconductor device 120 is completed according to the process given above.

Applying the manufacturing process shown in FIGS. 6A to 6D allows photolithography to be performed only once when forming the first protective film 40 to enclose the periphery of the oxide semiconductor film 20. Accordingly, the manufacturing process is simplified.

### Third Embodiment

Next, a third embodiment will be described.

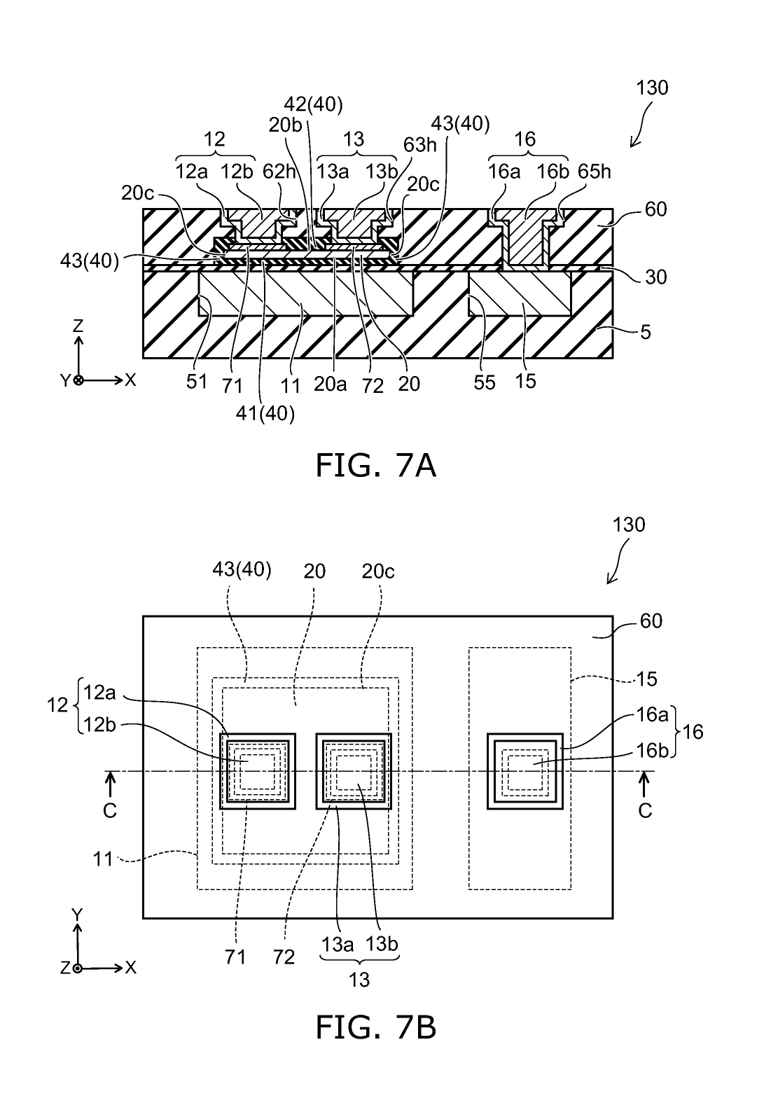

FIGS. 7A and 7B are schematic views illustrating a semiconductor device according to a third embodiment.

FIG. 7A shows a schematic cross-sectional view of a semiconductor device 130 according to the third embodiment. FIG. 7B shows a schematic plan view of the semiconductor device 130 according to the third embodiment. The schematic cross-sectional view shown in FIG. 7A is a cross-sectional view along C-C of FIG. 7B.

The semiconductor device 130, as shown in FIG. 7A, includes a first electrode 11, an oxide semiconductor film 20, an insulating film 30, a first protective film 40, a second electrode 12, and a third electrode 13. The semiconductor device 130 further includes a first conductive barrier film (a first portion) 71 provided between the oxide semiconductor film 20 and the second electrode 12, and, for example, a second conductive barrier film (a second portion) 72 provided between the oxide semiconductor film 20 and the third electrode 13. The first conductive barrier film 71 and the second conductive barrier film 72 are the third protective film.

The first conductive barrier film 71 contacts, for example, the oxide semiconductor film 20 and the first barrier film 12a, respectively. The second conductive barrier film 72 contacts, for example, the oxide semiconductor film 20 and the second barrier film 13a, respectively.

The first conductive barrier film 71 and the second conductive barrier film 72 have a function for suppressing substances including hydrogen from being introduced from the outer side of the oxide semiconductor film 20 into the inner side thereof. In the first conductive barrier film 71 and the second conductive barrier film 72, materials may be used that includes one selected from the group consisting of, for example, Ti, TiN, Ta, Tan, TiC, TiAlN, Zr or Nb. The first conductive barrier film 71 and the second conductive barrier film 72 may have a single layer structure using a above material, or it may have a stacked structure in which a plurality of the above materials are stacked.

Because the first conductive barrier film 71 and the second conductive barrier film 72 are provided in the semiconductor device 130, substances including hydrogen or the like can be more effectively suppressed from being introduced into the oxide semiconductor film 20 than when these films are not provided.

Here, increasing a thickness of the first barrier film 12a and the second barrier film 13a improve the effectiveness of preventing diffusion of Cu and the suppression of substances including hydrogen or the like from being introduced into the oxide semiconductor film 20. However, if the thicknesses of the first barrier film 12a and the second barrier film 13a become too thick, the thicknesses of the first conductive portion 12b and the second conductive portion 13b becomes thinner which may lead to an increase in interconnection resistance.

Providing the first conductive barrier film 71 and the second conductive barrier film 72 as in the semiconductor device 130, substances including hydrogen or the like are suppressed from diffusing into the oxide semiconductor film 20 without increasing the thicknesses of the first barrier film 12a and the second barrier film 13a. Accordingly, the thicknesses of the first conductive portion 12b and the second conductive portion 13b need not to be reduced and interconnection resistance does not increase.

Next, an example of a method for manufacturing the semiconductor device 130 will be described.

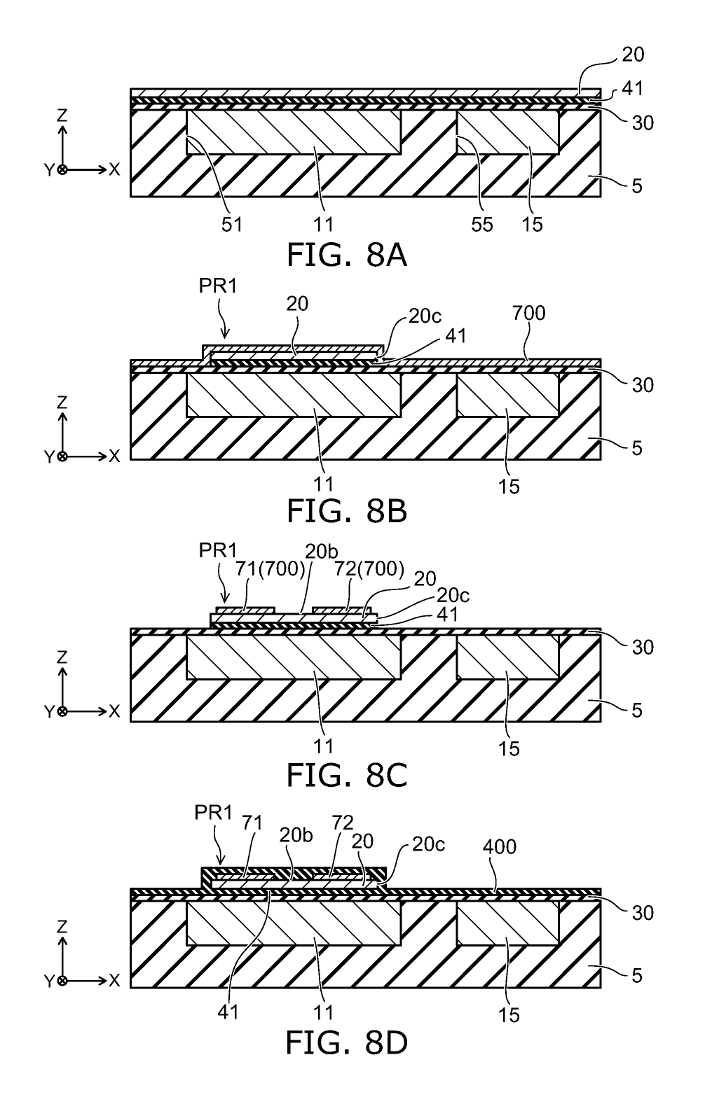

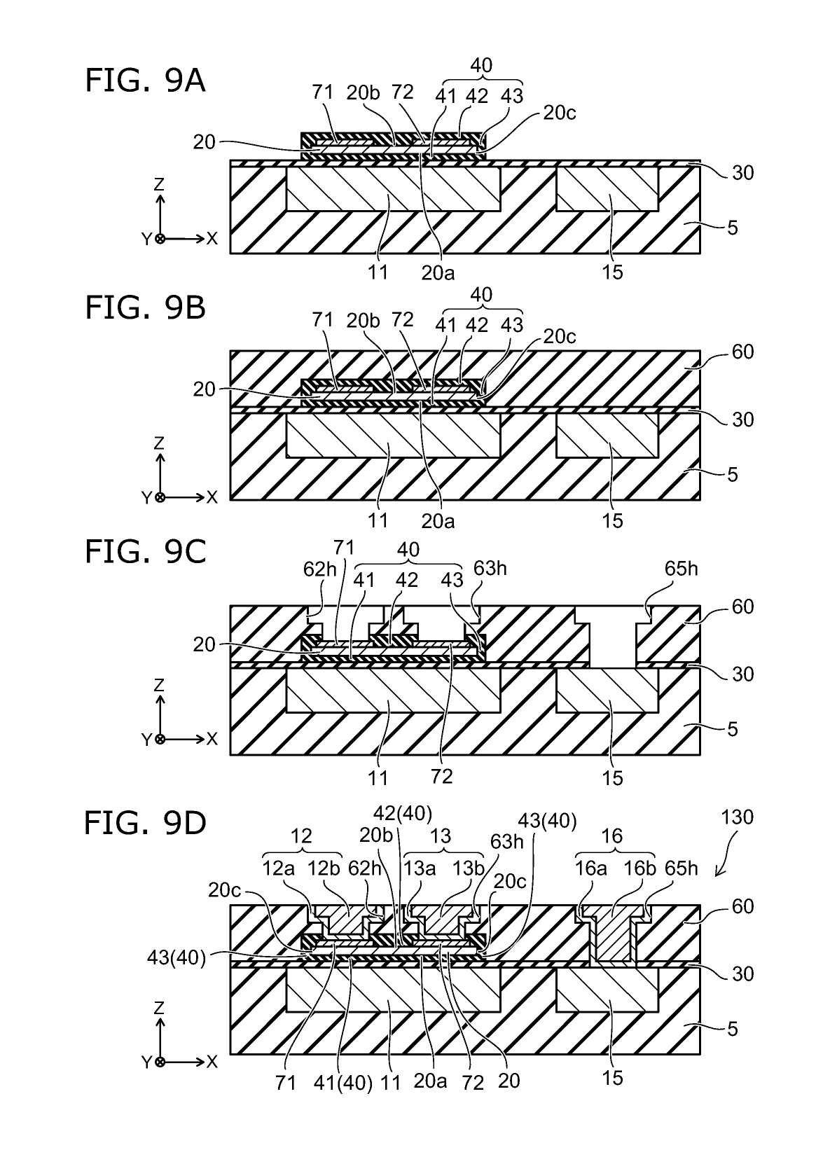

FIG. 8A to FIG. 9D are schematic cross-sectional views showing one example of the method for manufacturing the semiconductor device.

First, as shown in FIG. 8A, the first electrode 11 and the interconnection 15 that conducts with the first electrode 11 are formed in the insulating portion 5. The insulating portion 5 is provided, for example, on a substrate not illustrated. The first electrode 11 and the interconnection 15 are formed by, for example, the damascene method. In other words, etching is performed on a portion of the insulating portion 5 to form the grooves 51 and 55. Next, Cu, for example, is formed on the insulating portion 5 so as to fill in the grooves 51 and 55. Thereafter, the Cu is removed using CMP to leave only the Cu embedded in the grooves 51 and 55.

Next, as shown in FIG. 8B, a portion of the oxide semiconductor film 20 and a portion of the first film 41 are removed. The portion of the oxide semiconductor film 20 and the portion of the first film 41 may be removed by, for example, photolithography and etching. The oxide semiconductor film 20 and the first film 41 on the interconnection 15 are removed by the etching. The oxide semiconductor film 20 and the first film 41 are left on the first electrode 11. By this, a pattern region PR1 of the oxide semiconductor film 20 and the first film 41 is formed on the first electrode 11. The pattern region PR1 is formed in an island shape on the first electrode 11. The side face (the third face 20c) is formed on the oxide semiconductor film 20 by the etching.

Next, a conductive material film 700 is formed so as to cover the pattern region PR1. The conductive material film 700 is formed on the pattern region PR1 and on the insulating film 30. In the conductive material film 700, a material may be used that includes one selected from the group consisting of, for example, Ti, TiN, Ta, Tan, TiC, TiAlN, Zr, or Nb. The conductive material film 700 is formed using, for example, a sputtering method. A thickness of the conductive material film 700 may be, for example, not less than 1 nm and not more than 10 nm. The conductive material film 700 may have a single layer structure using the above material, or it may have a stacked structure in which a plurality of materials are stacked.

Next, as shown in FIG. 8C, a portion of the conductive material film 700 is removed. The portion of the conductive material film 700 may be removed by, for example, photolithography and etching. The conductive material film 700 is left in an island shape on the oxide semiconductor film 20 by the etching. The remaining conductive material film 700 is the first conductive barrier film 71 and the second conductive barrier film 72.

Next, as shown in FIG. 8D, the protective film material film 400 is formed so as to cover the pattern region PR1, the first conductive barrier film 71, and the second conductive barrier film 72. The protective film material film 400 is formed on the pattern region PR1, on the first conductive barrier film 71, on the second conductive barrier film 72, and on the insulating film 30. A similar material to that used for, for example, the first film 41 may also be used for the protective film material film 400.

Next, as shown in FIG. 9A, a portion of the protective film material film 400 is removed such that only the portion that covers the pattern region PR1 remains. For example, photolithography and etching may be used so as to leave only the protective film material film 400 on the second face 20b of the oxide semiconductor film 20 and the protective film material film 400 on the third face 20c. The protective film material film 400 left on the second face 20b of the oxide semiconductor film 20 after the etching becomes the second film 42. Further, the protective film material film 400 left on the third face 20c of the oxide semiconductor film 20 becomes the third film 43. In other words, the first protective film 40 is formed to enclose the periphery of the oxide semiconductor film 20.

Note that the removal of the portion of the protective film material film 400 shown in FIG. 9A may not always be required. Once a portion of the protective film material film 400 shown in FIG. 9A is removed, subsequent etching of the protective film material film 400 is no longer necessary when forming the contact hole 65h on the interconnection 15. Therefore, etching conditions are alleviated when forming the contact hole 65h.

Next, as shown in FIG. 9B, the interlayer insulating film 60 is formed on the insulating film 30 and on the first protective film 40. The material, manufacturing method, and thickness of the interlayer insulating film 60 are similar to the method for manufacturing the semiconductor device 110.

Next, as shown in FIG. 9C, the contact holes 62h, 63h, and 65h are formed. The contact holes 62h and 63h are formed in the interlayer insulating film 60 and in the second film 42. The contact hole 65h is formed in the interlayer insulating film 60 and in the insulating film 30. The contact holes 62h, 63h, and 65h are formed by, for example, photolithography and etching. The contact hole 62h is formed from the upper face of the interlayer insulating film 60 to the first conductive barrier film 71. The contact hole 63h is formed from the upper face of the interlayer insulating film 60 to the second conductive barrier film 72. The contact hole 65h is formed from the upper face of the interlayer insulating film 60 to the interconnection 15.

Next, as shown in FIG. 9D, the second electrode 12, the third electrode 13, and the interconnection 16 are formed. First, the first barrier film 12a is formed on the inner wall and bottom of the contact hole 62h, the second barrier film 13a is formed on the inner wall and bottom of the contact hole 63h, and a third barrier film 16a is formed on the inner wall and bottom of the contact hole 65h. The first barrier film 12a contacts the first conductive barrier film 71. The second barrier film 13a contacts the second conductive barrier film 72. The third barrier film 16a contacts the interconnection 15. TaN, for example, is used in the first barrier film 12a, in the second barrier film 13a, and in the third barrier film 16a.

Next, the first conductive portion 12b is formed on the first barrier film 12a in the contact hole 62h, the second conductive portion 13b is formed on the second barrier film 13a in the contact hole 63h, and the third conductive portion 16b is formed on the third barrier film 16a in the contact hole 65h. Cu, for example, is used in the first conductive portion 12b, in the second conductive portion 13b, and in the third conductive portion 16b. The first conductive portion 12b, the second conductive portion 13b, and the third conductive portion 16b are formed using, for example, the damascene method. In other words, Cu, for example, is formed on the interlayer insulating film 60 so as to fill in the contact holes 62h, 63h, and 65h. Thereafter, the Cu is removed using CMP to leave only the Cu embedded in the contact holes 62h, 63h, and 65h.

Thereafter, a sintering process is performed using hydrogen if, for example, an Si-LSI is on the lower layer of the TFT. The semiconductor device 130 is completed according to the process given above.

According to the method for manufacturing this type of semiconductor device 130, substances (substances including hydrogen or the like) included in the first electrode 11 in the manufacturing process can be suppressed by the first film 41 from being introduced into the oxide semiconductor film 20. Furthermore, when a sintering process or the like is performed to form the second electrode 12 and the third electrode 13, substances (substances including hydrogen or the like) are suppressed by the second film 42 and the third film 43 from being introduced from the second face 20b side and the third face 20c side into an inner side of the oxide semiconductor film 20. Furthermore, substances (electrode material such as Cu and substances including hydrogen or the like) are effectively suppressed by the first conductive barrier film 71 and the second conductive barrier film 72 from being introduced from the second electrode 12 and the third electrode 13 into the oxide semiconductor film 20. By this, the semiconductor device 130 is provided that suppresses a drop in mobility, a drop in threshold voltage, and deterioration of the subthreshold characteristics.

Next, another example of a method for manufacturing the semiconductor device 130 will be described.

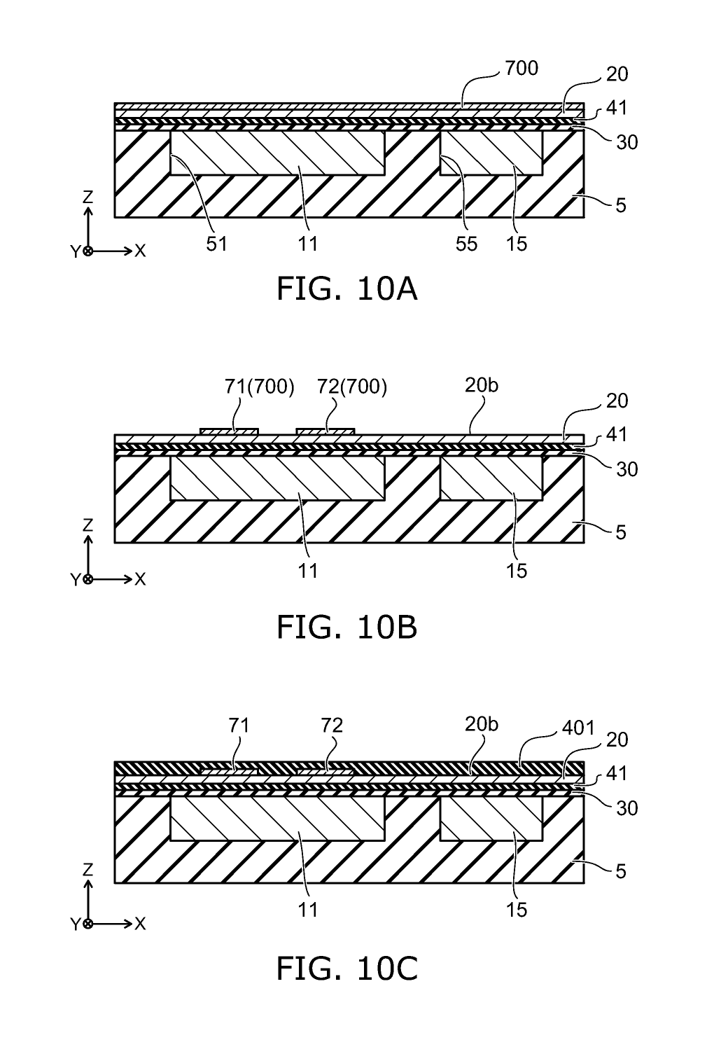

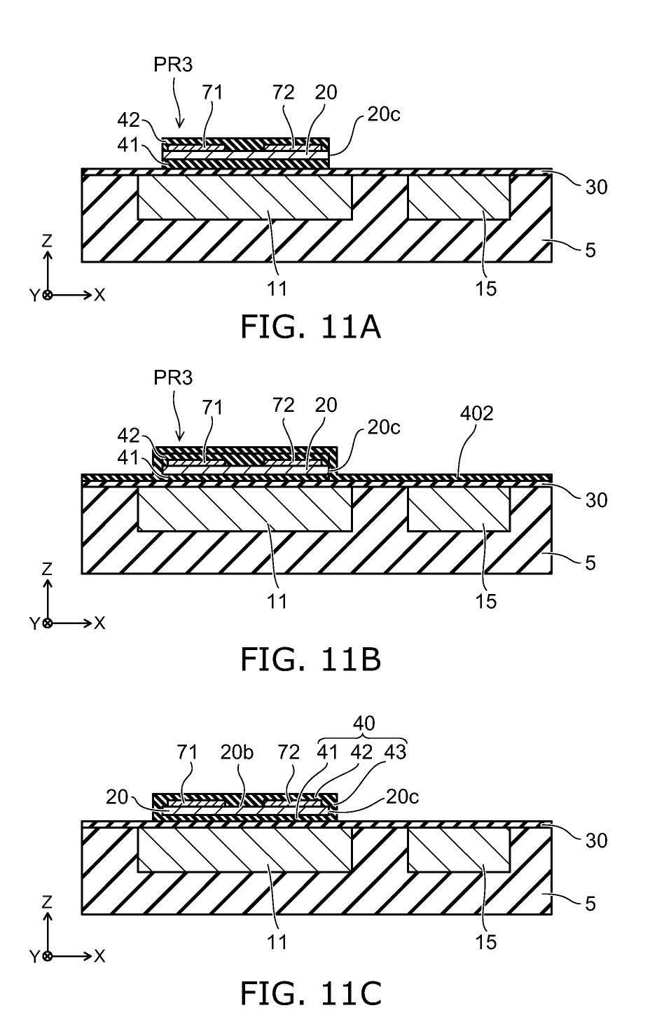

FIG. 10A to FIG. 11C are schematic cross-sectional views showing another example of the method for manufacturing the semiconductor device.

A portion of a process in the method for manufacturing the semiconductor device 130 is shown in FIG. 10A to FIG. 11C.

First, as shown in FIG. 10A, the first electrode 11 and the interconnection 15 that conducts with the first electrode 11 are formed in the insulating portion 5. Next, the insulating film 30, the first film 41, the oxide semiconductor film 20, and the conductive material film 700 are stacked in this order on the first electrode 11, the interconnection 15 and the insulating portion 5. The respective materials, manufacturing methods, and thicknesses of the insulating film 30, the first film 41, the oxide semiconductor film 20, and the second film 42 are similar to the method for manufacturing the semiconductor device shown in FIGS. 8A and 8B.

Next, as shown in FIG. 10B, a portion of the conductive material film 700 is removed. The portion of the conductive material film 700 may be removed by, for example, photolithography and etching. The conductive material film 700 is left in an island shape on the oxide semiconductor film 20 by the etching. The remaining conductive film 700 is the first conductive barrier film 71 and the second conductive barrier film 72.

Next, as shown in FIG. 10C, a first protective film material film 401 is formed on the oxide semiconductor film 20, the first conductive barrier film 71, and the second conductive barrier film 72. A similar material to that used for, for example, the first film 41 may also be used for the first protective film material film 401.

Next, as shown in FIG. 11A, a portion of the first protective film material film 401, a portion of the oxide semiconductor film 20, and a portion of the first film 41 are removed. The portion of the first protective film material film 401, the portion of the oxide semiconductor film 20, and the portion of the first film 41 may be removed by, for example, photolithography and etching. The first protective film material film 401, the oxide semiconductor film 20, and the first film 41 on the interconnection 15 are removed by the etching. The first protective film material film 401, the oxide semiconductor film 20, and the first film 41 on the first electrode 11 are left. By this, a pattern region PR3 of the second film 42, the first conductive barrier film 71, the second conductive barrier film 72, the oxide semiconductor film 20, and the first film 41 is formed on the first electrode 11. The pattern region PR3 is formed in an island shape on the first electrode 11. The side face (the third face 20c) is formed on the oxide semiconductor film 20 by the etching.

Next, as shown in FIG. 11B, a second protective film material film 402 is formed so as to cover the pattern region PR3. The second protective film material film 402 is formed on the pattern region PR3 (including on the third face 20c) and on the insulating film 30. A similar material to that used for, for example, the first film 41 may also be used for the second protective film material film 402.

Next, as shown in FIG. 11C, the second protective film material film 402 is etched back. The second protective film material film 402 is etched back only an amount equal to the thickness of the second protective film material film 402 formed on the insulating film 30. An anisotropic etching is used for the etching back. The etching rate in the Z direction of the anisotropic etching is greater than the etching rates in the X direction and the Y direction. The second protective film material film 402 on the insulating film 30 and the second protective film material film 402 on the second film 42 are removed by the etching back. The second protective film material film 402 provided on the third face 20c is left. Further, the second protective film material film 402 left on the third face 20c becomes the third film 43. In other words, the first protective film 40 is formed to enclose the periphery of the oxide semiconductor film 20.

The subsequent processes are the same as those illustrated in FIGS. 9C to 9D. The semiconductor device 130 is completed according to the process given above.

Applying the manufacturing process shown in FIG. 10A to FIG. 11C allows photolithography to be performed only once when forming the first protective film 40 to enclose the periphery of the oxide semiconductor film 20. Accordingly, the manufacturing process is simplified.

### Fourth Embodiment

Next, a fourth embodiment will be described.

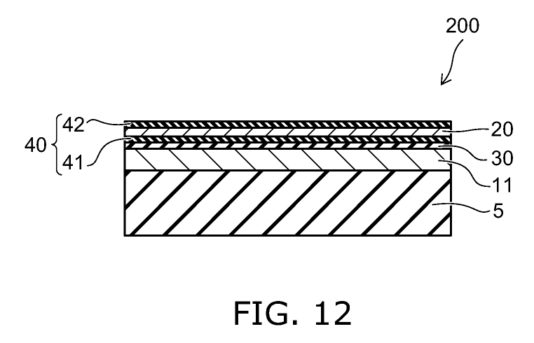

FIG. 12 is schematic cross-sectional view illustrating an example of a semiconductor device according to the fourth embodiment.

The semiconductor device 200 according to the fourth embodiment, as shown in FIG. 12, includes a first electrode 11, an oxide semiconductor film 20, an insulating film 30, and a first protective film 40. The semiconductor device 200 is a device having a metal insulator semiconductor (MIS) structure (for example, an MIS capacitor or an MIS diode).

The first electrode 11 is provided on, for example, the insulating portion 5. The first electrode 11 may be embedded in a groove provided in the insulating portion 5. Cu may be used, for example, for the first electrode 11.

The oxide semiconductor film 20 is provided on the first electrode 11. The oxide semiconductor film 20 includes a first face 20a on the first electrode 11 side and a second face 20b on a side opposite to the first face 20a. For example, In—Ga—Zn—O is provided for the oxide semiconductor film 20. An oxide including In or Zn other than In—Ga—Zn—O, such as In—O film, Zn—O film, In—Zn—O film, In—Ga—O film, Al—Zn—O film, or In—Al—Zn—O film may also be used for the oxide semiconductor film 20.

The insulating film 30 is provided between the first electrode 11 and the oxide semiconductor film 20. The insulating film 30 may be stacked, for example, on the first electrode 11. SiN, for example, may be used for the insulating film 30. Other than SiN, SiO₂, SiON or the like may be used for the insulating film 30. The use of Cu as the first electrode 11 and SiN as the insulating film 30 effectively suppresses the diffusion of Cu into the oxide semiconductor film 20.

The first protective film 40 includes a first film 41 and a second film 42. The first film 41 is provided between the insulating film 30 and the first face 20a. The first film 41 contacts, for example, the first face 20a. The second film 42 is provided on the second face 20b. The second film 42 contacts, for example, the second face 20b. Specifically, the oxide semiconductor film 20 is provided between the first film 41 and the second film 42.

The first protective film 40 suppresses foreign material from being introduced from the outer side of the oxide semiconductor film 20 into the inner side thereof. Foreign material includes substances including, for example, hydrogen. The first protective film 40 includes one selected from the group consisting of, for example, Al₂O₃, TiO₂, or Ta₂O₅). The material for the first film 41 may be the same or different material as that of the second film 42.

In the semiconductor device 200, the insulator (I) layer of the MIS structure includes the insulating film 30 and the first film 41. The first film 41 functions as a barrier film that suppresses substances (for example substances that include hydrogen) included in layers below the first film 41 from being introduced into the oxide semiconductor film 20. The second film 42 functions as a barrier film that suppresses substances (for example, substances that include hydrogen) from being introduced into the oxide semiconductor film 20 from the outer side of the second film 42.

In the semiconductor device 200, the oxide semiconductor film 20 is sandwiched between the first film 41 and the second film 42 so as to suppress substances including hydrogen or the like from being introduced from the outer side of the oxide semiconductor film 20 into the inner side thereof. By this, deterioration of the characteristics can be suppressed.

As described above, with the semiconductor device and the method for manufacturing the same according to embodiments, characteristics can be stabilized.

The embodiments have been described above, but the invention is not limited to these examples. For example, in the embodiments described above, examples were given using a TFT as the semiconductor devices 110, 120, and 130, but a transistor other than the TFT may also be used. Also, in the above described embodiments, when constituents are appropriately added, removed or changed in design by a person skilled in the art, or the characteristics of the various embodiments are appropriately combined; provided that the resulting configuration does not depart from the spirit of the invention, it falls within in the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
an oxide semiconductor film provided on the first electrode, the oxide semiconductor film including a first face on the first electrode side and a second face on a side opposite to the first face;
an insulating film provided between the first electrode and the oxide semiconductor film;
a first protective film including a first film and a second film, the first film being provided between the insulating film and the first face, the second film being provided on the second face, the first protective film being configured to suppress substances including hydrogen from being introduced from an outer side of the oxide semiconductor film into an inner side of the oxide semiconductor film;
a second electrode electrically connected to the oxide semiconductor film; and
a third electrode electrically connected to the oxide semiconductor film.

2. The device according to claim 1, wherein the first protective film is provided so as to cover a periphery of the oxide semiconductor film.

3. The device according to claim 1, wherein
the oxide semiconductor film further includes a third face provided between the first face and the second face, and the first protective film further includes a third film provided on the third face, the third film being provided between the first film and the second film.

4. The device according to claim 1, wherein the first protective film is an insulating oxide.

5. The device according to claim 4, wherein the first protective film includes one selected from the group consisting of Al₂O₃, TiO₂ or Ta₂O₅.

6. The device according to claim 1, further comprising:
a second protective film (Cu barrier) provided between the oxide semiconductor film and the second electrode, and between the oxide semiconductor film and the third electrode, the second protective layer suppressing a material of the second electrode and a material of the third electrode from being introduced into the oxide semiconductor film.

7. The device according to claim 6, wherein the second protective film includes TaN.

8. The device according to claim 1, further comprising:
a third protective film provided between the oxide semiconductor film and the second electrode, and between the oxide semiconductor film and the third electrode, the third protective film suppressing a substance including hydrogen from being introduced from the outer side of the oxide semiconductor film into the inner side of the oxide semiconductor film.

9. The device according to claim 8, wherein the third protective film includes one selected from the group consisting of Ti, TiN, Ta, TaN, TiC, TiAlN, Zr, or Nb.

10. The device according to claim 1, wherein the first electrode, the second electrode, and the third electrode include Cu, respectively.

11. The device according to claim 1, wherein the insulating film includes SiN.

12. The device according to claim 1, wherein the oxide semiconductor includes at least one of In—O and Zn—O.

13. A method for manufacturing a semiconductor device, comprising:
forming a first electrode on an insulating portion;
forming an insulating film on the first electrode, forming a first film on the insulating film, and forming an oxide semiconductor film on the first film;
selectively removing the oxide semiconductor film and the first film;
forming a second film on the oxide semiconductor film;
forming a first contact hole reaching the oxide semiconductor film in a portion of the second film and a second contact hole reaching the oxide semiconductor film in a portion of the second film; and
forming a second electrode electrically connected to the oxide semiconductor film in the first contact hole, and forming a third electrode electrically connected to the oxide semiconductor film in the second contact hole,
the first film and the second film being films suppressing a substance including hydrogen from being introduced from an outer side of the oxide semiconductor film into an inner side of the oxide semiconductor film.

14. A method for manufacturing a semiconductor device, comprising:
forming a first electrode on an insulating portion;
forming an insulating film on the first electrode, forming a first film on the insulating film, and forming an oxide semiconductor film on the first film;
selectively removing the oxide semiconductor film and the first film;
forming a conductive film on the oxide semiconductor film;
forming a first portion and a second portion by removing a portion of the conductive film;
forming a second film on the oxide semiconductor film, the first portion, and the second portion;
forming a first contact hole reaching the first portion in a portion of the second film, and a second contact hole reaching the second portion; and
forming a second electrode electrically connected to the first portion in the first contact hole, and forming a third electrode electrically connected to the second portion in the second contact hole,
the first film and the second film being films suppressing a substance including hydrogen from being introduced from an outer side of the oxide semiconductor film into an inner side of the oxide semiconductor film.

15. A method for manufacturing a semiconductor device, comprising:
forming a first electrode on an insulating portion;
forming an insulating film on the first electrode, forming a first film on the insulating film, forming an oxide semiconductor film on the first film, and forming a second film on the oxide semiconductor;
forming a pattern region by selectively removing the second film, the oxide semiconductor film, and the first film;
forming a third film so as to cover the pattern region;
etching the third film so as to leave a portion formed on a side face of the pattern region of the third film;
forming a first contact hole reaching the oxide semiconductor film in a portion of the second film and a second contact hole reaching the oxide semiconductor film in a portion of the second film; and
forming a second electrode electrically connected to the oxide semiconductor film in the first contact hole, and forming a third electrode electrically connected to the oxide semiconductor film in the second contact hole,
the first film, the second film, and the third film being films suppressing a substance including hydrogen from being introduced from an outer side of the oxide semiconductor film into an inner side of the oxide semiconductor film.

16. A method for manufacturing a semiconductor device, comprising:
forming a first electrode on an insulating portion;
forming an insulating film on the first electrode, forming a first film on the insulating film, forming an oxide semiconductor film on the first film, and forming a conductive film on the oxide semiconductor film;
forming a first portion and a second portion by removing a portion of the conductive film;
forming a second film on the oxide semiconductor film, the first portion, and the second portion;
forming a pattern region by selectively removing the second film, the oxide semiconductor film, and the first film;
forming a third film so as to cover the pattern region;
etching the third film so as to leave a portion formed on a side face of the pattern region of the third film;
forming a first contact hole reaching the first portion in a portion of the second film, and forming a second contact hole reaching the second portion; and
forming a second electrode electrically connected to the first portion in the first contact hole, and forming a third electrode electrically connected to the second portion in the second contact hole,
the first film and the second film being films suppress a substance including hydrogen from being introduced from an outer side of the oxide semiconductor film into an inner side of the oxide semiconductor film.
